(19) United States
(12) Patent Application Publication
(10) Pub. No.: US 2026/0239853 A1
(43) Pub. Date: Aug. 13, 2026

(54) DISPLAY PANEL INCLUDING AUXILIARY COLOR FILTER AND ELECTRONIC DEVICE INCLUDING THE SAME

(71) Applicant: SAMSUNG DISPLAY CO., LTD., YONGIN-SI (KR)

(72) Inventors: Kyuwon Cho, YONGIN-SI (KR); Sujeong Kim, YONGIN-SI (KR); Yunho Lee, YONGIN-SI (KR); Keunchan Oh, YONGIN-SI (KR)

(21) Appl. No.: 19/536,893

(22) Filed: Feb. 11, 2026

(30) Foreign Application Priority Data
Feb. 12, 2025 (KR) 10-2025-0018094

(51) Int. Cl. H10K 59/38

(52) U.S. Cl. CPC H10K 59/38

(57) ABSTRACT

A display panel includes a substrate and first to third light-emitting diodes on the substrate, spaced apart from one another. A touch sensing layer is disposed on the first to third light-emitting diodes and has first to third openings that respectively overlap the first to third light-emitting diodes. A first auxiliary color filter is disposed in the first opening in the touch sensing layer. A second auxiliary color filter is disposed in the second opening in the touch sensing layer. A first color filter is disposed on the touch sensing layer and overlaps the first light-emitting diode. A second color filter is disposed on the touch sensing layer and overlaps the second light-emitting diode. A third color filter is disposed on the touch sensing layer and overlaps the third light-emitting diode. The first auxiliary color filter and the second auxiliary color filter transmit light of a same color.

### CROSS-REFERENCE TO RELATED APPLICATION

This application claims priority under 35 U.S.C. §119 to Korean Patent Application No. 10-2025-0018094, filed on Feb. 12, 2025, in the Korean Intellectual Property Office, the disclosure of which is incorporated by reference herein in its entirety.

### TECHNICAL FIELD

The present disclosure relates to a display panel and, more specifically, to a display panel including an auxiliary color filter and an electronic device including the display panel.

### Discussion of The Related Art

An electronic device may be configured to display images using a display panel provided therein. The display panel may be configured to visually display data. The display panel may be further configured to provide images using light-emitting diodes. As display panels are now being used for a wide variety of electronic devices, various attempts have been made to design display panels with improved quality.

### SUMMARY

A display panel includes a substrate, a first light-emitting diode, a second light-emitting diode, and a third light-emitting diode each disposed on the substrate and spaced apart from each other. A touch sensing layer is disposed on each of the first light-emitting diode, the second light-emitting diode, and the third light-emitting diode. The touch sensing layer has a first opening that overlaps the first light-emitting diode, and a second opening that overlaps the second light-emitting diode. A first auxiliary color filter is disposed in the first opening in the touch sensing layer, a second auxiliary color filter is disposed in the second opening in the touch sensing layer, a first color filter is disposed on the touch sensing layer and overlaps the first light-emitting diode, a second color filter is disposed on the touch sensing layer and overlaps the second light-emitting diode, and a third color filter is disposed on the touch sensing layer and overlaps the third light-emitting diode. The first auxiliary color filter and the second auxiliary color filter are configured to transmit light of a same color.

The first color filter may be in direct contact with an upper surface of the first auxiliary color filter, and the second color filter may be in direct contact with an upper surface of the second auxiliary color filter.

The first auxiliary color filter and the second auxiliary color filter may each include scatterers.

The first auxiliary color filter may have a closed loop shape overlapping an edge region of the first color filter, and the second auxiliary color filter may have a closed loop shape overlapping an edge region of the second color filter.

An upper surface of the first auxiliary color filter, an upper surface of the second auxiliary color filter, and an upper surface of the touch sensing layer may be disposed within a same plane.

The first auxiliary color filter and the second auxiliary color filter may be configured to transmit light of a color that is a combined result of first light emitted from the first light-emitting diode and second light emitted from the second light-emitting diode.

The first auxiliary color filter and the second auxiliary color filter may each include yellow dye.

The first auxiliary color filter and the second auxiliary color filter may each be configured to block light in a wavelength of 500 nm or less.

A display panel includes a substrate, a first light-emitting diode disposed over the substrate and configured to emit a first light of a first color, a second light-emitting diode disposed over the substrate and configured to emit a second light of a second color, a third light-emitting diode disposed over the substrate and configured to emit a third light of a third color, a first color filter overlapping the first light-emitting diode and transmitting light of the first color, a second color filter overlapping the second light-emitting diode and transmitting light of the second color, a third color filter overlapping the third light-emitting diode and transmitting light of the third color, a first auxiliary color filter disposed between the first light-emitting diode and the first color filter, and a second auxiliary color filter disposed between the second light-emitting diode and the second color filter. The first auxiliary color filter and the second auxiliary color filter are each configured to transmit light of a color that is a combined result of the first light and the second light.

The display panel may further include a touch sensing layer disposed between the first to third color filters and the first to third light-emitting diodes, and including a first opening that overlaps the first light-emitting diode and a second opening that overlaps the second light-emitting diode. The first auxiliary color filter may be disposed in the first opening of the touch sensing layer, and the second auxiliary color filter may be disposed in the second opening of the touch sensing layer.

An upper surface of the first auxiliary color filter, an upper surface of the second auxiliary color filter, and an upper surface of the touch sensing layer may be disposed within a same plane.

The first auxiliary color filter and the second auxiliary color filter may each include scatterers.

The first auxiliary color filter may have a closed loop shape overlapping an edge region of the first color filter, and the second auxiliary color filter may have a closed loop shape overlapping an edge region of the second color filter.

The first auxiliary color filter and the second auxiliary color filter may each include yellow dye.

The first auxiliary color filter and the second auxiliary color filter may each be configured to block light in a wavelength of 500 nm or less.

The first light-emitting diode, the second light-emitting diode, and the third light-emitting diode may be configured to emit light of different colors from each other.

An electronic device includes a display panel, and a processor configured to drive the display panel. The display panel includes a substrate, a first light-emitting diode, a second light-emitting diode, and a third light-emitting diode disposed on the substrate and spaced apart from each other. A touch sensing layer is disposed on the first light-emitting diode, the second light-emitting diode, and the third light-emitting diode. The touch sensing layer has a first opening that overlaps the first light-emitting diode, and a second opening that overlaps the second light-emitting diode. A first auxiliary color filter is disposed in the first opening in the touch sensing layer, a second auxiliary color filter is disposed in the second opening in the touch sensing layer, a first color filter is disposed on the touch sensing layer and overlaps the first light-emitting diode, a second color filter is disposed on the touch sensing layer and overlaps the second light-emitting diode, and a third color filter is disposed on the touch sensing layer and overlaps the third light-emitting diode. The first auxiliary color filter and the second auxiliary color filter are configured to transmit light of a same color.

The first auxiliary color filter and the second auxiliary color filter may each include scatterers.

The first auxiliary color filter and the second auxiliary color filter may each include yellow dye.

The first auxiliary color filter and the second auxiliary color filter may be configured to block light in a wavelength of 500 nm or less.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a block diagram of an electronic device according to an embodiment;

FIGS. 2, 3, and 4 are perspective schematic views of an electronic device according to various embodiments;

FIG. 5 is a schematic plan view of an electronic device according to an embodiment;

FIG. 6 is an equivalent circuit diagram of a display panel according to an embodiment;

FIG. 7 is a cross-sectional view of a display panel according to an embodiment;

FIG. 8A is a cross-sectional view of a display panel according to an embodiment;

FIG. 8B is a plan view of a display panel according to an embodiment;

FIG. 8C is a plan view of a display panel according to an embodiment;

FIG. 9 is a cross-sectional view of a display panel according to an embodiment; and

FIG. 10 is a cross-sectional view of a display panel according to an embodiment.

### DETAILED DESCRIPTION

Reference will now be made in detail to embodiments, examples of which are illustrated in the accompanying drawings, wherein like reference numerals may refer to like elements throughout the specification and the drawings. In this regard, the present embodiments may have different forms and should not necessarily be construed as being limited to the descriptions set forth herein. Accordingly, the embodiments are described below, by referring to the figures, to explain aspects of the present description. As used herein, the term "and/or" includes any and all combinations of one or more of the associated listed items. Throughout the disclosure, the expression "at least one of a, b, and c" indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not necessarily limited to embodiments described below and may be implemented in various forms.

Hereinafter, embodiments will be described with reference to the accompanying drawings, wherein, like or corresponding elements are given like reference numerals when describing with reference to the drawings, and to the extent that an element is not described in detail with respect to this figure, it may be understood that the element is at least similar to a corresponding element that has been described elsewhere within the present disclosure.

In embodiments below, when various elements such as a layer, a region, a plate, and the like are disposed "on" another element, not only the elements may be disposed "directly on" the other element, but another element may be disposed therebetween. In addition, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

In embodiments below, terms such as first and second are not necessarily used in a limited meaning and may be used for the purpose of distinguishing one element from another.

In embodiments below, the terms "comprise," or "include" as used herein specify the presence of stated features or elements but do not preclude the addition of one or more other features or elements.

In the present specification, "A and/or B" means A or B, or A and B. In addition, "at least one of A and B" means A or B, or A and B.

In embodiments below, when a layer, region, or element is referred to as being connected, it includes not only a case where the layer, region, or element is directly connected, but also a case where the layer, region, or element is indirectly connected with another layer, region, or element disposed therebetween. For example, in the present specification, when a layer, region, or element is referred to as being electrically connected, it represents a case where the layer, region, or element is directly electrically connected and/or a case where the layer, region, or element is indirectly electrically connected with another layer, region, or element disposed therebetween.

In embodiments below, expression of an x direction may denote a +x direction and a -x direction, for example, ±x directions. In embodiments below, expression of a y direction may denote a +y direction and a -y direction, for example, ±y directions. In embodiments below, expression of a z direction may denote a +z direction and a -z direction, for example, ±z directions.

A display panel (or a display device) according to embodiments is applicable to various electronic devices. An electronic device according to embodiments may include a display panel (or a display device), and further include a module or a device having another additional function other than the display panel (or the display device).

Embodiments of the present disclosure relate to a display panel and electronic device incorporating an improved color filtering structure for light-emitting diode (LED) displays. This structure may enhance display quality and optimize manufacturing processes, particularly those involving inkjet deposition.

In embodiments of the present disclosure, auxiliary color filters are located beneath primary color filters in the display stack. The display panel includes three primary LEDs (typically red, green, and blue), each positioned over a substrate. A touch sensing layer with specific openings is located above these LEDs. In the openings corresponding to two of the LEDs (e.g., the red and green), auxiliary color filters are positioned. These auxiliary filters are configured to transmit the same color, e.g., yellow, formed by the overlap of red and green light.

Above the touch sensing layer, the main color filters are deposited to correspond with each LED. The red, green, and blue color filters allow the passage of light in their respective spectral bands. By incorporating yellow auxiliary filters underneath the red and green color filters, embodiments of the present disclosure may eliminate the need to include yellow dye in the ink used for forming the red and green filters. This reduction in dye concentration decreases ink viscosity, making the inkjet printing process more efficient and less prone to defects like nozzle clogging or uneven spreading.

Additionally, the auxiliary color filters may include scatterers, which may be microscopic particles that diffuse light, further improving the uniformity and visibility of the emitted light. These auxiliary filters may have a closed-loop or frame shape, overlapping the edges of the primary color filters and contributing to improved color purity and contrast.

This dual-layer color filtering approach not only enhances display performance but also supports more reliable and scalable manufacturing by addressing limitations in ink formulation and jetting performance. The display structure is especially applicable to high-performance consumer electronics, including smartphones, tablets, smartwatches, and other devices requiring vibrant and accurate color reproduction.

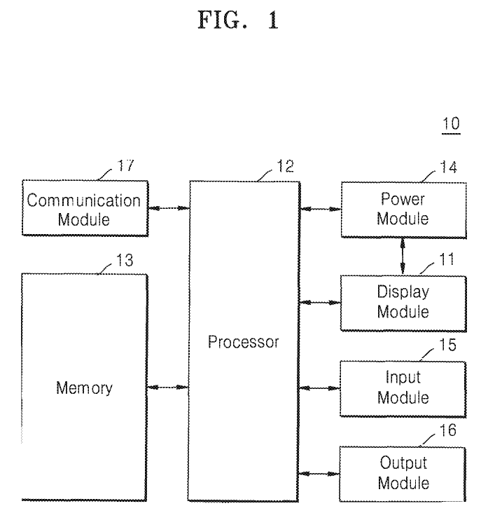

FIG. 1 is a block diagram of an electronic device 10 according to an embodiment. Referring to FIG. 1, the electronic device 10 may include a display panel 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. In an embodiment, the processor 12 may be divided into two or more portions from a functional or structural viewpoint. As an example, the processor 12 may include a main processor in the form of a first driving chip, including a central processing unit, and an auxiliary processor in the form of a second driving chip, including a controller, wherein the auxiliary processor receives image signals from the main processor and processes the image signals to match interface specifications of the display panel 11.

The memory 13 may include at least one of a non-volatile memory and a volatile memory. The memory 13 may store data for operations of the processor 12 or the display panel 11. When the processor 12 executes an application stored in the memory 13, an image data signal and/or an input control signal may be transferred to the display panel 11, and the display panel 11 may process a provided signal and output image information through a display screen.

The power module 14 may include a power supply module such as a power adapter or a battery unit, and a power converting module converting power supplied by the power supply module and generating power required for operations of the electronic device 10. Power conversion by the power converting module may include DC-DC conversion, AC-DC conversion, and DC-AC conversion and is not necessarily limited thereto.

The electronic device 10 may further include an input module 15, an output module 16 that provides an output other than generating an image, and/or a communication module 17.

The input module 15 may provide input information to the processor 12 and/or the display panel 11. The input module 15 may include not only a physical button, a keyboard, and a microphone, but also various kinds of sensor modules. Examples of sensor modules may include not only touch sensors, pressure sensors, distance sensors, position sensors, digitizers, motion recognition sensors, camera sensors, photodetectors, photoelectric conversion sensors, temperature sensors, but also biometric sensors such as blood pressure sensors, blood sugar sensors, electrocardiogram sensors, and heart rate sensors.

The output module 16 may receive information other than images received from the processor 12 and may provide the information to a user. Examples of the output module 16 may include a sound module, a haptic module, and/or a light-emitting module, and include a unique functional module (e.g., a cooling module of a refrigerator) of other devices.

The communication module 17 is a module responsible for transmission/reception of information between the electronic device 10 and an external device, and may include a receiver and a transmitter. The communication module 17 may include various wireless communication modules such as mobile communication modules, Wi-Fi (wireless fidelity) modules, and Bluetooth modules, and include various wired communication modules.

At least one element of the electronic device 10 may be included in the display device. In addition, some of individual modules functionally included in one module may be included in the display device, and some other may be provided separately from the display device. As an example, the display device may include the display panel 11, and the processor 12, the memory 13, and the power module 14 may be provided in the form of another device within the electronic device 10 instead of the display device. As an example, the power module 14 may be prepared in the display device, may provide power to the processor 12 and the memory 13 provided within the electronic device 10 instead of the display device, and the disclosure is not necessarily limited thereto.

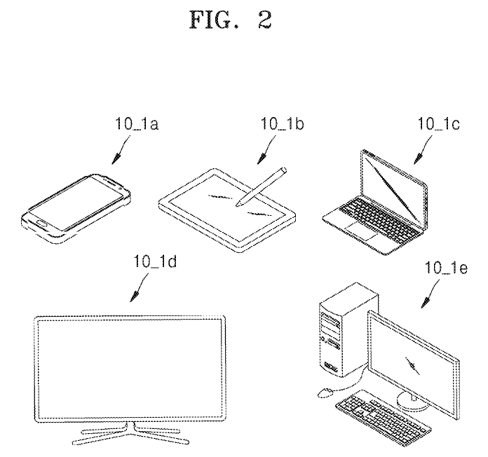

FIGS. 2, 3, and 4 are schematic views of an electronic device according to various embodiments. FIGS. 2, 3, and 4 show examples of various electronic devices to which the display panel according to embodiments is applied.

FIG. 2 shows, as an example of the electronic device, a smartphone 10_1a, a tablet computer 10_1b, a laptop/notebook computer 10_1c, a TV 10_1d, and a computer monitor 10_1e.

The smartphone 10_1a may include an input module such as a touch sensor, and a communication module in addition to the display panel. The smartphone 10_1a may process information received through the communication module or other input modules and display the information through the display panel of the display device.

Similar to the smartphone 10_1a, the tablet computer 10_1b, the laptop/notebook computer 10_1c, the TV 10_1d, and the computer monitor 10_1e may include the display panel and the input module and may further include the communication module depending on a case.

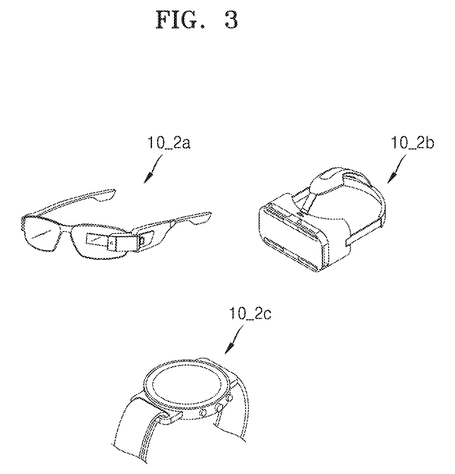

FIG. 3 shows, as an example, a case where the electronic device including the display panel is applied to a wearable electronic device. The wearable electronic device may include a smart glasses 10_2a, a head mount display 10_2b, and a smartwatch 10_2c.

The smart glasses 10_2a and the head mount display 10_2b may include the display panel outputting display images and a reflector reflecting the output display screen and providing the display screen to a user’s eyes, and may provide a screen of a virtual reality or an augmented reality to a user through this.

The smartwatch 10_2c may include a biometric sensor as an input device and provide, through the display panel, a user with bio information recognized through the biometric sensor.

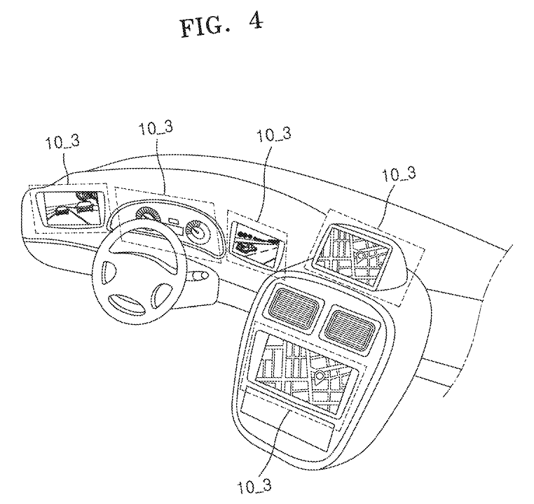

FIG. 4 shows, as an example, a case where the electronic device including the display panel is applied to a vehicle. As an example, an electronic device 10_3 may be applied to an instrument board, a center facia or the like of an automobile, or may be applied to a center information display (CID) disposed on a dashboard of an automobile or a room mirror display replacing a side mirror.

The electronic device to which the display panel according to embodiments is applied may include not only devices centered on displays such as digital billboards, electronic signboards, and/or portable game consoles, but also various home appliances that display information through a display panel, such as a refrigerator, a washing machine, a dryer, an air conditioner, and/or a robotic vacuum cleaner. In addition, in the case where the display panel has a function transmitting light, the display module is applicable to a smart window or an electronic device such as a transparent display device and the like, that display a background and a display image together. The kind of the electronic device according to an embodiment is not necessarily limited to the example, and various other electronic devices may be applied.

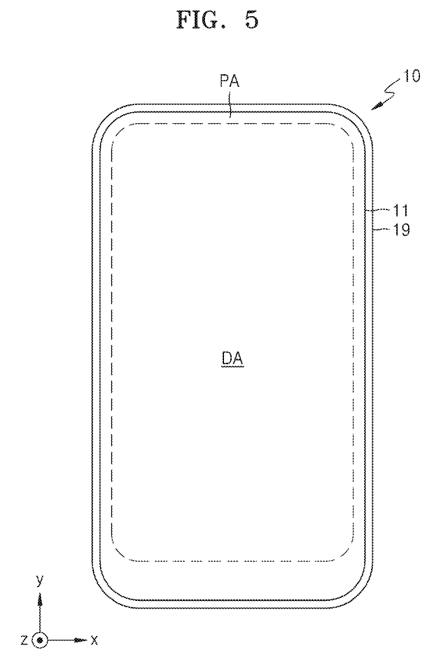

FIG. 5 is a schematic plan view of the electronic device 10 according to an embodiment.

Although FIG. 5 shows, as an embodiment, a case where the electronic device 10 is a smartphone, this is for convenience of description, and the disclosure is not necessarily limited thereto. The electronic device 10 may include the display panel 11 and a housing 19. In an embodiment, the display panel 11 may be accommodated within the housing 19. The housing 19 is not necessarily implemented in only the form shown in FIG. 5, and any housing may belong to the housing 19 denoted by the present specification without limitation in kind and shape as long as the housing provides a space in which the display panel 11 may be accommodated. As an example, the housing 19 does not need to surround the display panel 11 entirely, and may partially cover the display panel 11.

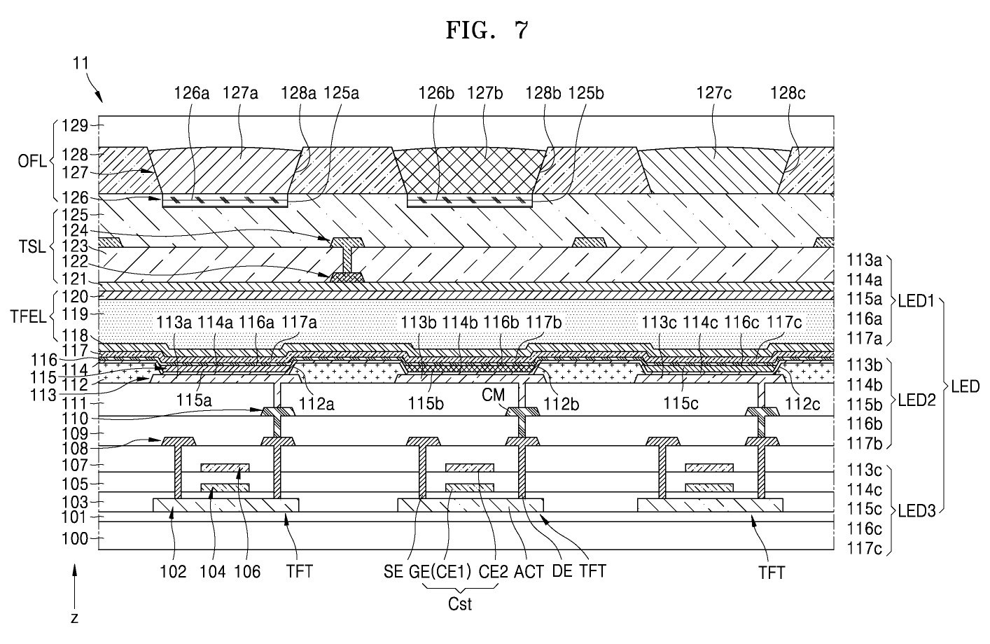

Referring to FIG. 5, the display panel 11 may include a display area DA and a peripheral area PA outside the display area DA. For example, the display area DA and the peripheral area PA outside the display area DA may be defined in the display panel 11. For example, the display panel 11 may include a substrate 100 (see FIG. 7), and the display area DA and the peripheral area PA may be defined in the substrate 100.

A pixel may be disposed in the display area DA. The pixel may include at least one light-emitting diode and a pixel circuit connected to the light-emitting diode to drive the light-emitting diode. The light-emitting diode driven through the pixel circuit may be configured to emit light of a specific color (e.g., a specific wavelength band). The display panel 11 may provide images through light emitted from a plurality of light-emitting diodes provided to a plurality of pixels. In an embodiment, the pixel may include a plurality of sub-pixels that are grouped. In an embodiment, one sub-pixel may include one corresponding light-emitting diode and one corresponding sub-pixel circuit. In an embodiment, light-emitting diodes respectively provided to a plurality of sub-pixels that are grouped as one pixel may be configured to emit light of different colors (e.g., wavelength bands) from each other. The peripheral area PA is a non-display area, and signal lines and/or voltage lines for driving the light-emitting diodes may be disposed in the peripheral area PA.

Although it is shown in FIG. 5 that the display panel 11 and the display area DA have an approximately quadrilateral shape with round corners, the disclosure is not necessarily limited thereto. The display panel 11 and/or the display area DA may have various shapes, for example, a polygon, a circular shape, an elliptical shape, an irregular shape, and the like.

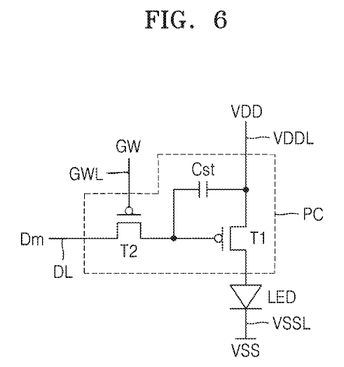

FIG. 6 is an equivalent circuit diagram of the display panel according to an embodiment.

Referring to FIG. 6, a light-emitting diode LED corresponding to a pixel may be electrically connected to a pixel circuit PC. The pixel circuit PC may include a first transistor T1, a second transistor T2, and a storage capacitor Cst. The pixel circuit PC may be electrically connected to a signal line and a voltage line. The signal line may include a scan signal line GWL and a data line DL, and the voltage line may include a first voltage line VDDL and a second voltage line VSSL.

The second transistor T2 is a data-write transistor and may be electrically connected to the scan signal line GWL and the data line DL. The scan signal line GWL may provide a scan signal GW to a gate of the second transistor T2. The second transistor T2 is configured to transfer a data signal Dm to the first transistor T1 (e.g., a gate of the first transistor T1) according to a scan signal GW input from the scan signal line GWL, wherein the data signal Dm is input from the data line DL.

The storage capacitor Cst may be electrically connected to the second transistor T2 and the first voltage line VDDL and may store a voltage corresponding to a difference between a voltage transferred from the second transistor T2 and a first power voltage VDD supplied by the first voltage line VDDL.

The first transistor T1 is a driving transistor and may control a driving current flowing through the light-emitting diode LED. The first transistor T1 may be connected to the first voltage line VDDL and the storage capacitor Cst. The first transistor T1 may control the driving current flowing from the first voltage line VDDL to the light-emitting diode LED in response to a voltage value stored in the storage capacitor Cst. The light-emitting diode LED may be configured to emit light having a preset brightness corresponding to the driving current. A first electrode (e.g., a pixel electrode or an anode) of the light-emitting diode LED may be electrically connected to the first transistor T1, and a second electrode (e.g., an opposite electrode or a cathode) may be electrically connected to the second voltage line VSSL supplying a second power voltage VSS.

Although it is shown in FIG. 6 that the pixel circuit PC includes one switching transistor (e.g., the second transistor T2) and one capacitor (e.g., the storage capacitor Cst), the pixel circuit PC may include two or more switching transistors and/or two or more capacitors in another embodiment.

FIG. 7 is a cross-sectional view of the display panel 11 according to an embodiment. FIG. 7 may be a cross-sectional view of the display area DA (see FIG. 5) of the display panel 11.

Referring to FIG. 7, the light-emitting diode LED and a thin-film transistor TFT corresponding to each light-emitting diode LED may be disposed on the substate 100. A thin-film encapsulation layer TFEL, a touch sensing layer TSL, and an optical functional layer OFL may be sequentially disposed on the light-emitting diode LED.

In an embodiment, a first light-emitting diode LED1, a second light-emitting diode LED2, and a third light-emitting diode LED3, and thin-film transistors TFT respectively corresponding thereto may be disposed on the substrate 100. Each of the first light-emitting diode LED1, the second light-emitting diode LED2, and the third light-emitting diode LED3 may be connected to a thin-film transistor TFT corresponding thereto.

In an embodiment, the first light-emitting diode LED1, the second light-emitting diode LED2, and the third light-emitting diode LED3 may respectively belong to separate pixels, or may together belong to one single pixel. In the case where the first light-emitting diode LED1, the second light-emitting diode LED2, and the third light-emitting diode LED3 belong to one pixel, the first light-emitting diode LED1, the second light-emitting diode LED2, and the third light-emitting diode LED3 may respectively belong to sub-pixels (e.g., first to third sub-pixels) corresponding thereto. The thin-film transistor TFT connected to each of the first light-emitting diode LED1, the second light-emitting diode LED2, and the third light-emitting diode LED3 may correspond to a portion of the pixel circuit PC described above with reference to FIG. 6. In an embodiment, the thin-film transistor TFT may correspond to the first transistor T1 of FIG. 6.

A first insulating layer 101 may be disposed on the substrate 100. The first insulating layer 101 may cover the substrate 100 entirely. The first insulating layer 101 may planarize and protect the upper surface of the substrate 100. The first insulating layer 101 may include an inorganic insulating material. In an embodiment, the first insulating layer 101 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layered structure or a multi-layered structure of the above materials. In an embodiment, the first insulating layer 101 may be a buffer layer.

The thin-film transistor TFT may be disposed on the first insulating layer 101. The thin-film transistor TFT may include an active layer ACT and a gate electrode GE. The thin-film transistors TFT respectively corresponding to the first to third light-emitting diodes LED1, LED2, and LED3 may be disposed on the first insulating layer 101. The structures of the thin-film transistors TFT respectively corresponding to the first to third light-emitting diodes LED1, LED2, and LED3 may be similar to each other.

A semiconductor layer 102 may be disposed on the first insulating layer 101. The semiconductor layer 102 may include the active layer ACT. The active layer ACT may be patterned to correspond to each thin-film transistor TFT. The active layer ACT may include a drain region overlapping a drain electrode DE, a source region overlapping a source electrode SE, and a channel region between the drain region and the source region. The drain region and the source region may be doped with impurities (e.g., dopants).

A second insulating layer 103 may be disposed on the semiconductor layer 102. The second insulating layer 103 may include an inorganic insulating material. In an embodiment, the second insulating layer 103 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layered structure or a multi-layered structure of the above materials. In an embodiment, the second insulating layer 103 may be a first gate insulating layer. In an embodiment, as shown in FIG. 7, the second insulating layer 103 may cover the semiconductor layer 102 and the first insulating layer 101 entirely. In an embodiment, the second insulating layer 103 may be patterned to cover only the active layer ACT and not to cover the upper surface of the first insulating layer 101 between the active layers ACT. In an embodiment, the second insulating layer 103 may be patterned to cover only a partial region (e.g., a region, for example, a channel region overlapping the gate electrode GE) of each active layer ACT.

The storage capacitor Cst may be disposed on the second insulating layer 103. The storage capacitor Cst may include a first capacitor electrode CE1 and a second capacitor electrode CE2. The second capacitor electrode CE2 may be disposed over the first capacitor electrode CE1.

A first conductive layer 104 may be disposed on the second insulating layer 103. The first conductive layer 104 may include the gate electrode GE and the first capacitor electrode CE1. The gate electrode GE may be patterned to correspond to each thin-film transistor TFT. The gate electrode GE may overlap the channel region of the active layer ACT. The first capacitor electrode CE1 may be patterned to correspond to each storage capacitor Cst. In an embodiment, the gate electrode GE and the first capacitor electrode CE1 may be formed of a single uninterrupted, continuous structure as shown in FIG. 7. In an embodiment, the gate electrode GE and the first capacitor electrode CE1 may be individually provided. In an embodiment, the first conductive layer 104 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and include a single-layered structure or a multi-layered structure including the above materials.

A third insulating layer 105 may be disposed on the first conductive layer 104. The third insulating layer 105 may cover the first conductive layer 104 entirely. The third insulating layer 105 may include an inorganic insulating material. In an embodiment, the third insulating layer 105 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layered structure or a multi-layered structure of the above materials. In an embodiment, the third insulating layer 105 may be a second gate insulating layer.

A second conductive layer 106 may be disposed on the third insulating layer 105. The second conductive layer 106 may include the second capacitor electrode CE2 of each storage capacitor Cst. The second capacitor electrode CE2 may be patterned to correspond to each storage capacitor Cst. The second capacitor electrode CE2 may overlap the first capacitor electrode CE1. In an embodiment, the second conductive layer 106 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and include a single-layered structure or a multi-layered structure including the above materials.

A fourth insulating layer 107 may be disposed on the second conductive layer 106. The fourth insulating layer 107 may cover the second conductive layer 106 entirely. The fourth insulating layer 107 may include an inorganic insulating material. In an embodiment, the fourth insulating layer 107 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layered structure or a multi-layered structure of the above materials. In an embodiment, the fourth insulating layer 107 may be an interlayer insulating layer.

A third conductive layer 108 may be disposed on the fourth insulating layer 107. The third conductive layer 108 may include the source electrode SE and the drain electrode DE of each thin-film transistor TFT. The source electrode SE and the drain electrode DE may be patterned to correspond to each thin-film transistor TFT. The source electrode SE may overlap the source region of the active layer ACT. The drain electrode DE may overlap the drain region of the active layer ACT. The source electrode SE may be connected to the active layer ACT (e.g., the source region of the active layer ACT) through an opening defined in the second to fourth insulating layers 103, 105, and 107. The drain electrode DE may be connected to the active layer ACT (e.g., the drain region of the active layer ACT) through an opening defined in the second to fourth insulating layers 103, 105, and 107. In an embodiment, the third conductive layer 108 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and include a single-layered structure or a multi-layered structure including the above materials.

A fifth insulating layer 109 may be disposed on the third conductive layer 108. An opening overlapping the drain electrode DE may be defined in the fifth insulating layer 109. The fifth insulating layer 109 may include an organic insulating material. In an embodiment, the fifth insulating layer 109 may include an organic insulating layer including a general-purpose polymer such as benzocyclobutene, polyimide, hexamethyldisiloxane, polymethylmethacrylate or polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and have a single-layered structure or a multi-layered structure of the above material. In an embodiment, the fifth insulating layer 109 may be a first via layer.

A fourth conductive layer 110 may be disposed on the fifth insulating layer 109. The fourth conductive layer 110 may include contact metals CM respectively corresponding to the first to third light-emitting diodes LED1, LED2, and LED3. The contact metal CM may be patterned to overlap a corresponding light-emitting diode LED. The contact metal CM may be connected to a corresponding drain electrode DE through an opening defined in the fifth insulating layer 109. In an embodiment, the fourth conductive layer 110 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and include a single-layered structure or a multi-layered structure including the above materials.

A sixth insulating layer 111 may be disposed on the fourth conductive layer 110. An opening overlapping each contact metal CM of the fourth conductive layer 110 may be defined in the sixth insulating layer 111. The sixth insulating layer 111 may include an organic insulating material. In an embodiment, the sixth insulating layer 111 may include an organic insulating layer including a general-purpose polymer such as benzocyclobutene, polyimide, hexamethyldisiloxane, polymethylmethacrylate or polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and have a single-layered structure or a multi-layered structure of the above material. In an embodiment, the sixth insulating layer 111 may be a second via layer.

The plurality of light-emitting diodes LED may be disposed on the sixth insulating layer 111. In an embodiment, the first to third light-emitting diodes LED1, LED2, LED3 may be disposed on the sixth insulating layer 111. Each light-emitting diode LED may include a pixel electrode, a functional layer, an emission layer, and an opposite electrode corresponding thereto. In an embodiment, the first light-emitting diode LED1 may include a first pixel electrode 113a, a first lower functional layer 114a, a first emission layer 115a, a first upper functional layer 116a, and a first opposite electrode 117a. In an embodiment, the second light-emitting diode LED2 may include a second pixel electrode 113b, a second lower functional layer 114b, a second emission layer 115b, a second upper functional layer 116b, and a second opposite electrode 117b. In an embodiment, the third light-emitting diode LED3 may include a third pixel electrode 113c, a third lower functional layer 114c, a third emission layer 115c, a third upper functional layer 116c, and a third opposite electrode 117c. The emission layer of each light-emitting diode LED may be configured to emit light through a current flowing through the emission layer due to an electrical potential difference between the pixel electrode and the opposite electrode, and accordingly, the light-emitting diode LED may be configured emit light.

The fifth conductive layer 113 may be disposed on the sixth insulating layer 111. The fifth conductive layer 113 may include the first pixel electrode 113a, the second pixel electrode 113b, and the third pixel electrode 113c. The first pixel electrode 113a, the second pixel electrode 113b, and the third pixel electrode 113c may be individually patterned and apart from each other. Each of the first pixel electrode 113a, the second pixel electrode 113b, and the third pixel electrode 113c may be connected to a corresponding thin-film transistor TFT through a corresponding contact metal CM and a corresponding drain electrode DE. In an embodiment, the fifth conductive layer 113 may include a conductive oxide including indium tin oxide (ITO), indium zinc oxide (IZO), zinc oxide (ZnO), indium oxide (In₂O₃), indium gallium oxide (IGO), or aluminum zinc oxide (AZO). In an embodiment, the fifth conductive layer 113 may include silver (Ag), magnesium (Mg), aluminum (Al), platinum (Pt), palladium (Pd), gold (Au), nickel (Ni), neodymium (Nd), iridium (Ir), chromium (Cr), or a compound thereof. The construction and material of the fifth conductive layer 113 are not necessarily limited thereto and may be variously modified.

A pixel-defining layer 112 may be disposed on the fifth conductive layer 113 and the sixth insulating layer 111. The pixel-defining layer 112 may include a plurality of emission openings overlapping the plurality of pixel electrodes of the fifth conductive layer 113. For example, the pixel-defining layer 112 may cover the edge (or the edge region) of each pixel electrode of the fifth conductive layer 113.

In an embodiment, the pixel-defining layer 112 may include a first emission opening 112a overlapping the first pixel electrode 113a. For example, the pixel-defining layer 112 may cover the edge (or the edge region) of the first pixel electrode 113a. In an embodiment, an emission area of the first light-emitting diode LED1 may be defined by the first emission opening 112a.

In an embodiment, the pixel-defining layer 112 may include a second emission opening 112b overlapping the second pixel electrode 113b. For example, the pixel-defining layer 112 may cover the edge (or the edge region) of the second pixel electrode 113b. In an embodiment, an emission area of the second light-emitting diode LED2 may be defined by the second emission opening 112b.

In an embodiment, the pixel-defining layer 112 may include a third emission opening 112c overlapping the third pixel electrode 113c. For example, the pixel-defining layer 112 may cover the edge (or the edge region) of the third pixel electrode 113c. In an embodiment, an emission area of the third light-emitting diode LED3 may be defined by the third emission opening 112c.

The lower functional layer 114, the emission layer 115, and the upper functional layer 116 may be sequentially disposed on the pixel-defining layer 112 and the fifth conductive layer 113.

The lower functional layer 114 may include a first lower functional layer 114a, a second lower functional layer 114b, and a third lower functional layer 114c. In an embodiment, the lower functional layer 114 may be formed of a single uninterrupted, continuous structure. In an embodiment, a portion of the lower functional layer 114 overlapping the first pixel electrode 113a may be defined as the first lower functional layer 114a. In an embodiment, a portion of the lower functional layer 114 overlapping the second pixel electrode 113b may be defined as the second lower functional layer 114b. In an embodiment, a portion of the lower functional layer 114 overlapping the third pixel electrode 113c may be defined as the third lower functional layer 114c. In an embodiment, the lower functional layer 114 may be disposed (e.g., patterned) to be separated from each other and to correspond to each light-emitting diode LED.

The upper functional layer 116 may include a first upper functional layer 116a, a second upper functional layer 116b, and a third upper functional layer 116c. In an embodiment, the upper functional layer 116 may be formed of a single uninterrupted, continuous structure. In an embodiment, a portion of the upper functional layer 116 overlapping the first pixel electrode 113a may be defined as the first upper functional layer 116a. In an embodiment, a portion of the upper functional layer 116 overlapping the second pixel electrode 113b may be defined as the second upper functional layer 116b. In an embodiment, a portion of the upper functional layer 116 overlapping the third pixel electrode 113c may be defined as the third upper functional layer 116c. In an embodiment, the lower functional layer 114 may be disposed (e.g., patterned) to be separated from each other and to correspond to each light-emitting diode LED.

In an embodiment, the lower functional layer 114 may include at least one of an electron transport layer (ETL) and an electron injection layer (EIL), and the upper functional layer 116 may include at least one of a hole transport layer (HTL) and a hole injection layer (HIL). In an embodiment, the upper functional layer 116 may include at least one of an ETL and an EIL, and the lower functional layer 114 may include at least one of an HTL and an HIL.

The emission layer 115 may be disposed between the lower functional layer 114 and the upper functional layer 116. In an embodiment, the emission layer 115 may be disposed (e.g., patterned) to be separated from each other and to correspond to each light-emitting diode LED. In an embodiment, the first emission layer 115a may be disposed between the first lower functional layer 114a and the first upper functional layer 116a. In an embodiment, the first emission layer 115a may be disposed inside the first emission opening 112a of the pixel-defining layer 112. In an embodiment, the second emission layer 115b may be disposed between the second lower functional layer 114b and the second upper functional layer 116b. In an embodiment, the second emission layer 115b may be disposed inside the second emission opening 112b of the pixel-defining layer 112. In an embodiment, the third emission layer 115c may be disposed between the third lower functional layer 114c and the third upper functional layer 116c. In an embodiment, the third emission layer 115c may be disposed inside the third emission opening 112c of the pixel-defining layer 112.

In an embodiment, the emission layer 115 may include a low molecular weight material or a polymer material configured to emit light when a preset electrical potential difference is applied (or when a preset current flows). In an embodiment, the first emission layer 115a, the second emission layer 115b, and the third emission layer 115c may include different materials from each other. In an embodiment, the first emission layer 115a, the second emission layer 115b, and the third emission layer 115c may be configured to emit light of different colors (for example, wavelength bands) from each other. In an embodiment, the first emission layer 115a may be configured to emit red light when a current flows. In an embodiment, the second emission layer 115b may be configured to emit green light when a current flows. In an embodiment, the third emission layer 115c may be configured to emit blue light when a current flows.

The sixth conductive layer 117 may be disposed on the upper functional layer 116. The sixth conductive layer 117 may include an opposite electrode of the light-emitting diode LED. The sixth conductive layer 117 may be formed of a single uninterrupted, continuous structure over the first to third light-emitting diodes LED1, LED2, and LED3 and may cover the upper functional layer 116. A portion of the sixth conductive layer 117 overlapping the first pixel electrode 113a, the first lower functional layer 114a, the first emission layer 115a, and the first upper functional layer 116a may be defined as the first opposite electrode 117a. A portion of the sixth conductive layer 117 overlapping the second pixel electrode 113b, the second lower functional layer 114b, the second emission layer 115b, and the second upper functional layer 116b may be defined as the second opposite electrode 117b. A portion of the sixth conductive layer 117 overlapping the third pixel electrode 113c, the third lower functional layer 114c, the third emission layer 115c, and the third upper functional layer 116c may be defined as the third opposite electrode 117c.

The sixth conductive layer 117 may include a conductive material. In an embodiment, the sixth conductive layer 117 may include a transparent layer (or a semi-transparent layer) including silver (Ag), magnesium (Mg), aluminum (Al), platinum (Pt), palladium (Pd), gold (Au), nickel (Ni), neodymium (Nd), iridium (Ir), chromium (Cr), or an alloy thereof. Alternatively, the sixth conductive layer 117 may further include a layer on the transparent layer (or the semi-transparent layer) including the above materials, wherein the layer includes a material such as indium tin oxide (ITO), indium zinc oxide (IZO), zinc oxide (ZnO), or indium oxide (In₂O₃).

The thin-film encapsulation layer TFEL may be disposed on the sixth conductive layer 117. The thin-film encapsulation layer TFEL may cover the sixth conductive layer 117 entirely. The thin-film encapsulation layer TFEL may include at least one inorganic encapsulation layer and at least one organic encapsulation layer. In an embodiment, the thin-film encapsulation layer TFEL may include a first inorganic encapsulation layer 118, a second inorganic encapsulation layer 120, and an organic encapsulation layer 119, wherein the organic encapsulation layer 119 is between the first inorganic encapsulation layer 118 and the second inorganic encapsulation layer 120. In an embodiment, the first inorganic encapsulation layer 118 may cover the sixth conductive layer 117 entirely. In an embodiment, the organic encapsulation layer 119 may be provided as a planarization layer.

In an embodiment, the first inorganic encapsulation layer 118 and/or the second inorganic encapsulation layer 120 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂). The organic encapsulation layer 119 may include an organic insulating material. In an embodiment, the organic encapsulation layer 119 may include a polymer-based material. The polymer-based material may include, as an example, a silicon-base resin, an acryl-based resin, an epoxy-based resin, polyimide, and polyethylene. The disclosure is not necessarily limited to the thin-film encapsulation layer TFEL of this structure, and the number of one or more inorganic encapsulation layers, the number of one or more organic encapsulation layers, and a stacking order may be variously modified.

The touch sensing layer TSL may be disposed on the thin-film encapsulation layer TFEL, for example, the second inorganic encapsulation layer 120. The touch sensing layer TSL may sense an external input, for example, a touch of an object such as a finger or a stylus/pen, and allow the display panel 11 to obtain coordinate information corresponding to the touched position. The touch sensing layer TSL may include at least one conductive layer and at least one insulating layer.

The touch sensing layer TSL may include a first touch insulating layer 121, a first touch electrode layer 122, a second touch insulating layer 123, a second touch electrode layer 124, and a third touch insulating layer 125. The first touch insulating layer 121 may cover the second inorganic encapsulation layer 120. The first touch electrode layer 122 may be disposed on the first touch insulating layer 121. The second touch insulating layer 123 may be disposed on the first touch electrode layer 122. The second touch electrode layer 124 may be disposed on the second touch insulating layer 123. The third touch insulating layer 125 may be disposed on the second touch electrode layer 124. In an embodiment, the first touch insulating layer 121 may include an inorganic insulating material. In an embodiment, the second touch insulating layer 123 and the third touch insulating layer 125 may include an organic insulating material.

The first touch electrode layer 122 and the second touch electrode layer 124 may be connected to each other through a contact hole defined in the second touch insulating layer 123. In an embodiment, the second touch electrode layer 124 may be a sensing electrode, and the first touch electrode layer 122 may be a bridge electrode. In an embodiment, the first touch electrode layer 122 and the second touch electrode layer 124 may be patterned not to overlap the light-emitting diode LED. In an embodiment, the first touch electrode layer 122 and the second touch electrode layer 124 may overlap the pixel-defining layer 112. In an embodiment, the first touch electrode layer 122 and the second touch electrode layer 124 may have a mesh (or a net) shape surrounding the light-emitting diode LED. In an embodiment, the first touch electrode layer 122 and the second touch electrode layer 124 of the touch sensing layer TSL may be configured to measure touch using a self-capacitive method or a mutual capacitive method.

In an embodiment, a first opening 125a overlapping the first light-emitting diode LED1 and a second opening 125b overlapping the second light-emitting diode LED2 may be defined in the touch sensing layer TSL. In an embodiment, the first opening 125a and the second opening 125b may be defined in the third touch insulating layer 125.

The optical functional layer OFL may be disposed on the touch sensing layer TSL. The optical functional layer OFL may include an auxiliary color filter layer 126, a color filter layer 127, a first light-blocking layer 128, and an overcoat layer 129.

The auxiliary color filter layer 126 may include a first auxiliary color filter layer 126a and a second auxiliary color filter layer 126b. In an embodiment, the first auxiliary color filter layer 126a may be disposed in the touch sensing layer TSL, for example, the first opening 125a of the third touch insulating layer 125. In an embodiment, the second auxiliary color filter layer 126b may be disposed in the touch sensing layer TSL, for example, the second opening 125b of the third touch insulating layer 125. In an embodiment, the first auxiliary color filter layer 126a may fill the first opening 125a entirely. In an embodiment, the second auxiliary color filter layer 126b may fill the second opening 125b entirely. In an embodiment, the upper surface of the first auxiliary color filter layer 126a, the upper surface of the second auxiliary color filter layer 126b, and the upper surface of the third touch insulating layer 125 may be disposed within the same plane.

The color filter layer 127 may include a first color filter 127a, a second color filter 127b, and a third color filter 127c. In an embodiment, the first color filter 127a may overlap the first light-emitting diode LED1 and the first auxiliary color filter 126a. In an embodiment, the first color filter 127a may be disposed on the first auxiliary color filter 126a. In an embodiment, the first auxiliary color filter 126a may be disposed between the first color filter 127a and the first light-emitting diode LED1. In an embodiment, the first color filter 127a and the first auxiliary color filter 126a may be in direct contact with each other. In an embodiment, the lower surface of the first color filter 127a and the upper surface of the first auxiliary color filter 126a may be in direct contact with each other. In an embodiment, the second color filter 127b may be disposed on the second auxiliary color filter 126b. In an embodiment, the second auxiliary color filter 126b may be disposed between the second color filter 127b and the second light-emitting diode LED2. In an embodiment, the second color filter 127b and the second auxiliary color filter 126b may be in direct contact with each other. In an embodiment, the lower surface of the second color filter 127b and the upper surface of the second auxiliary color filter 126b may be in direct contact with each other.

The first light-blocking layer 128 may overlap the pixel-defining layer 112 and may be disposed on the touch sensing layer TSL. A third opening 128a overlapping the first light-emitting diode LED1, a fourth opening 128b overlapping the second light-emitting diode LED2, and a fifth opening 128c overlapping the third light-emitting diode LED3 may be defined in the first light-blocking layer 128. In an embodiment, the third opening 128a of the first light-blocking layer 128 may overlap the first opening 125a of the third touch insulating layer 125. In an embodiment, the fourth opening 128b of the first light-blocking layer 128 may overlap the second opening 125b of the third touch insulating layer 125. In an embodiment, the first color filter 127a may be disposed in the third opening 128a of the first light-blocking layer 128. In an embodiment, the second color filter 127b may be disposed in the fourth opening 128b of the first light-blocking layer 128. In an embodiment, the third color filter 127c may be disposed in the fifth opening 128c of the first light-blocking layer 128.

In an embodiment, because the first light-blocking layer 128 prevents external (e.g., ambient) light from reaching the first touch electrode layer 122 or the second touch electrode layer 124, the first light-blocking layer 128 may prevent the first touch electrode layer 122 or the second touch electrode layer 124 from reflecting the external (e.g., ambient) light and being observable to a user. In an embodiment, the first light-blocking layer 128 may increase the brightness and/or color reproduction by preventing light emitted from one of the light-emitting diodes LED from entering a path of light of an adjacent light-emitting diode LED.

The overcoat layer 129 may cover the color filter layer 127 and the first light-blocking layer 128 entirely and may be provided as a planarization layer. The overcoat layer 129 may include a light-transmissive material and include an organic insulating material.

In an embodiment, the first color filter 127a, the second color filter 127b, and the third color filter 127c may transmit light of different colors (for example, wavelength bands) from each other. In an embodiment, the first color filter 127a may transmit red light. In an embodiment, the second color filter 127b may transmit green light. In an embodiment, the third color filter 127c may transmit blue light.

In an embodiment, the first auxiliary color filter 126a and the second auxiliary color filter 126b may transmit light of the same color. In an embodiment, the first and second auxiliary color filters 126a and 126b may transmit light of a color in which light of a color transmitted by the first color filter 127a and light of a color transmitted by the second color filter 127b overlap each other. In an embodiment, the first color filter 127a may transmit red light, the second color filter 127b may transmit green light, and the first and second auxiliary color filters 126a and 126b may transmit yellow light in which red light and green light overlap each other. In an embodiment, the first and second auxiliary color filters 126a and 126b may include a yellow dye. In an embodiment, the first and second auxiliary color filters 126a and 126b may transmit yellow light, for example, light having a wavelength of 500 nm or more. In an embodiment, the first and second auxiliary color filters 126a and 126b may block light having a wavelength of 500 nm or less.

In an embodiment, at least one of the first color filter 127a, the second color filter 127b, and the third color filter 127c may be formed through an inkjet process. In an embodiment, the first color filter 127a may be formed by spraying first ink (e.g., including a red dye) in the third opening 128a of the first light-blocking layer 128, and then curing the same. In an embodiment, the second color filter 127b may be formed by spraying second ink (e.g., including a green dye) in the fourth opening 128b of the first light-blocking layer 128, and then curing the same. In an embodiment, the third color filter 127c may be formed by spraying third ink (e.g., including a blue dye) in the fifth opening 128c of the first light-blocking layer 128, and then curing the same.

In an embodiment, the first auxiliary color filter 126a and/or the second auxiliary color filter 126b may be formed through an inkjet process. In an embodiment, the first auxiliary color filter 126a may be formed by spraying ink (e.g., including a yellow dye) in the first opening 125a of the third touch insulating layer 125, and then curing the same. In an embodiment, the second auxiliary color filter 126b may be formed by spraying ink (e.g., including a yellow dye) in the second opening 125b of the third touch insulating layer 125, and then curing the same. In an embodiment, a process (e.g., an inkjet process) of forming the first auxiliary color filter 126a and a process (e.g., an inkjet process) of forming the second auxiliary color filter 126b may be simultaneously performed.

In a comparative example, in the case where the first auxiliary color filter 126a is not disposed, the first color filter 127a may have a transmittance of 0% or more with respect to light in a wavelength band, for example, of about 500 nm or less other than a wavelength band of red light (e.g., about 630 nm to about 750 nm). When the first color filter 127a has a transmittance with respect to light in even a wavelength of about 500 nm or less, light passing through the first color filter 127a might not be recognized as pure red light. Accordingly, because the first auxiliary color filter 126a is disposed under the first color filter 127a to block light in the wavelength band of about 500 nm or less, color characteristics of red light of the first color filter 127a may be improved. For example, because the first auxiliary color filter 126a is additionally disposed, light emitted from the first light-emitting diode LED1, passing through the first auxiliary color filter 126a and the first color filter 127a, and observable to a user may be made closer to pure red light.

In a comparative example, in the case where yellow dye included in the first auxiliary color filter 126a or a dye blocking light in the wavelength band of about 500 nm or less is included in the first ink, the viscosity of the first ink of the first color filter 127a may be greater than a case not including the dye. A high viscosity of ink may cause defects of an inkjet process. Accordingly, because the dye is not included in the first color filter 127a and has a separate color filter, for example, the first auxiliary color filter 126a, the viscosity of the first ink of the first color filter 127a may be reduced, and a defect rate of the inkjet process of disposing the first color filter 127a may be reduced.

In a comparative example, in the case where yellow dye included in the second auxiliary color filter 126b or a dye blocking light in the wavelength band of about 500 nm or less is included in the second ink, the viscosity of the second ink of the second color filter 127b may be greater than a case not including the dye. Similarly to the case of the first color filter 127a, because the dye is not included in the second color filter 127b and has a separate color filter, for example, the second auxiliary color filter 126b, the viscosity of the second ink of the second color filter 127b may be reduced, and a defect rate of the inkjet process of disposing the second color filter 127b may be reduced.

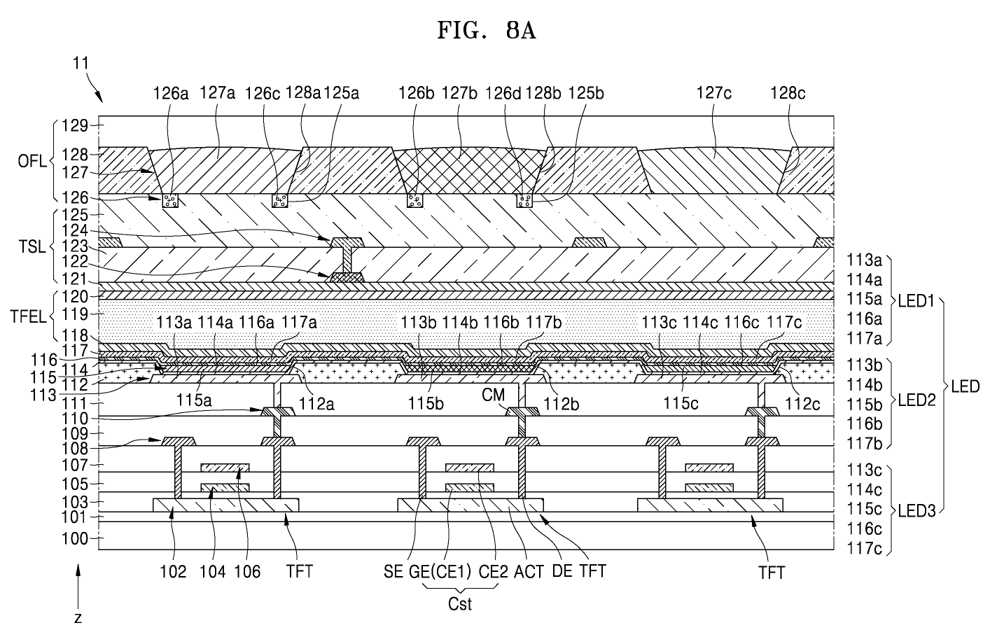

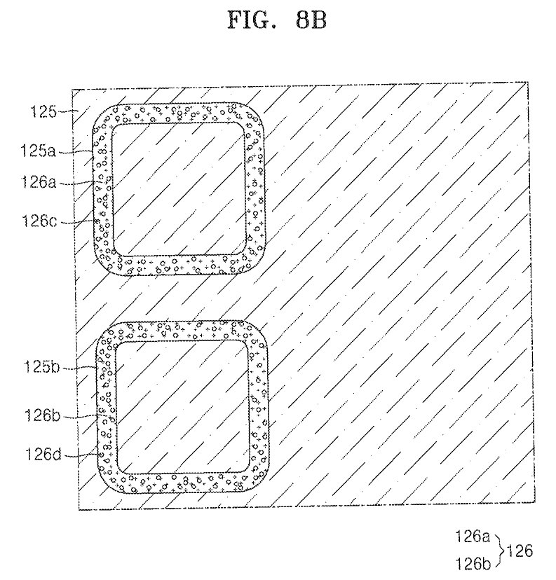

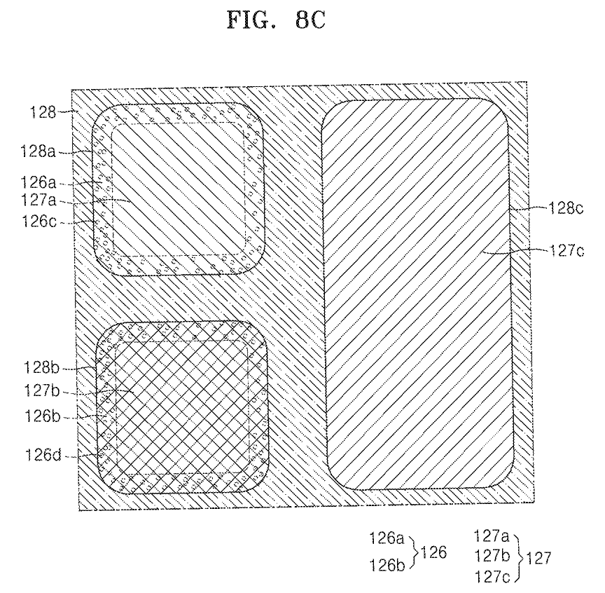

FIG. 8A is a cross-sectional view of the display panel according to an embodiment. FIG. 8B is a plan view of the display panel according to an embodiment. FIG. 8C is a plan view of the display panel according to an embodiment.

FIG. 8B shows the third touch insulating layer 125 and the auxiliary color filter layer 126, and FIG. 8C shows the first light-blocking layer 128 and the color filter layer 127.

Referring to FIGS. 8A, 8B, and 8C, the first auxiliary color filter 126a and the second auxiliary color filter 126b may include scatterers. In an embodiment, the first auxiliary color filter 126a may include first scatterers 126c. In an embodiment, the first scatterers 126c may be dispersed in the first auxiliary color filter 126a. In an embodiment, the first scatterers 126c may include light scattering particles, and scatter at least a portion of light passing through the first auxiliary color filter 126a.

In an embodiment, the second auxiliary color filter 126b may include second scatterers 126d. In an embodiment, the second scatterers 126d may be dispersed in the second auxiliary color filter 126b. In an embodiment, the second scatterers 126d may include light scattering particles, and scatter at least a portion of light passing through the second auxiliary color filter 126b.

Referring to FIGS. 8B and 8C, the first auxiliary color filter 126a may have a closed loop shape (or a frame) overlapping the edge region of the first color filter 127a. In an embodiment, the first opening 125a of the third touch insulating layer 125 may have a closed loop shape (or a frame) overlapping the edge region of the first color filter 127a, and the first auxiliary color filter 126a may fill the first opening 125a. In an embodiment, the first opening 125a of the third touch insulating layer 125 may have a closed loop shape (or a frame), the first auxiliary color filter 126a may fill the first opening 125a, the edge of the third opening 128a of the first light-blocking layer 128 may coincide with the first opening 125a of the third touch insulating layer 125, and the first color filter 127a may fill the third opening 128a. In an embodiment, the area (or the area of the first opening 125a) of the first auxiliary color filter 126a may be about 15 % or less of the area (or the area of the third opening 128a) of the first color filter 127a.

The second auxiliary color filter 126b may have a closed loop shape (or a frame) overlapping the edge region of the second color filter 127b. In an embodiment, the second opening 125b of the third touch insulating layer 125 may have a closed loop shape (or a frame) overlapping the edge region of the second color filter 127b, and the second auxiliary color filter 126b may fill the second opening 125b. In an embodiment, the second opening 125b of the third touch insulating layer 125 may have a closed loop shape (or a frame), the second auxiliary color filter 126b may fill the second opening 125b, the edge of the fourth opening 128b of the first light-blocking layer 128 may coincide with the second opening 125b of the third touch insulating layer 125, and the second color filter 127b may fill the fourth opening 128b. In an embodiment, the area (or the area of the second opening 125b) of the second auxiliary color filter 126b may be about 15 % or less of the area (or the area of the fourth opening 128b) of the second color filter 127b.

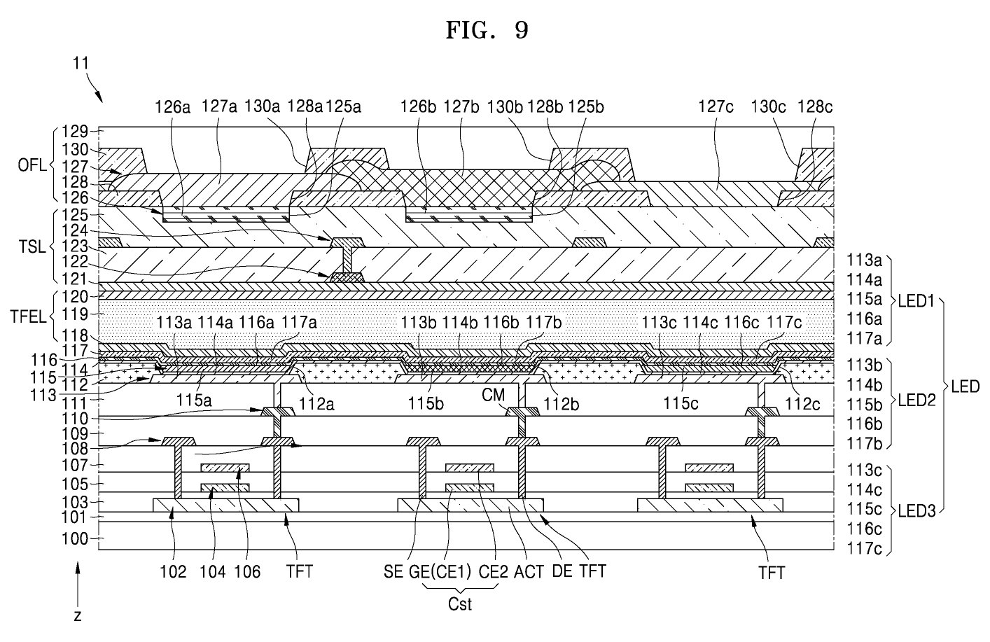

FIG. 9 is a cross-sectional view of the display panel according to an embodiment.

Referring to FIG. 9, two selected from the first color filter 127a, the second color filter 127b, and the third color filter 127c may overlap each other on the first light-blocking layer 128. In an embodiment, the first color filter 127a may fill the third opening 128a of the first light-blocking layer 128 entirely, and a portion of the first color filter 127a may be disposed on the upper surface of the first light-blocking layer 128. In an embodiment, the second color filter 127b may fill the fourth opening 128b of the first light-blocking layer 128 entirely, and a portion of the second color filter 127b may be disposed on the upper surface of the first light-blocking layer 128. In an embodiment, the third color filter 127c may fill the fifth opening 128c of the first light-blocking layer 128 entirely, and a portion of the third color filter 127c may be disposed on the upper surface of the first light-blocking layer 128.

In an embodiment, the first color filter 127a and the second color filter 127b may partially overlap each other on the first light-blocking layer 128. In an embodiment, the first color filter 127a and the second color filter 127b may overlap each other on a portion of the first light-blocking layer 128 disposed between the third opening 128a and the fourth opening 128b. In an embodiment, the second color filter 127b may be disposed on the first color filter 127a.

In an embodiment, the second color filter 127b and the third color filter 127c may partially overlap each other on the first light-blocking layer 128. In an embodiment, the second color filter 127b and the third color filter 127c may overlap each other on a portion of the first light-blocking layer 128 disposed between the fourth opening 128b and the fifth opening 128c. In an embodiment, the second color filter 127b may be disposed on the third color filter 127c.

In an embodiment, the first color filter 127a and the third color filter 127c may partially overlap each other on the first light-blocking layer 128. In an embodiment, the third color filter 127c may be disposed on the first color filter 127a.

However, the disclosure is not necessarily limited to the stacking order of the first to third color filters 127a, 127b, and 127c, and the stacking order of the first to third color filters 127a, 127b, and 127c may be variously modified.

A second light-blocking layer 130 may be disposed on the color filter layer 127. In an embodiment, the second light-blocking layer 130 may be disposed on the first light-blocking layer 128. In an embodiment, the second light-blocking layer 130 may cover at least two overlapping each other selected among the first to third color filters 127a, 127b, and 127c. In an embodiment, the second light-blocking layer 130 may cover a portion in which the first color filter 127a and the second color filter 127b overlap each other. In an embodiment, the second light-blocking layer 130 may cover a portion in which the second color filter 127b and the third color filter 127c overlap each other. In an embodiment, the second light-blocking layer 130 may cover a portion in which the first color filter 127a and the third color filter 127c overlap each other.

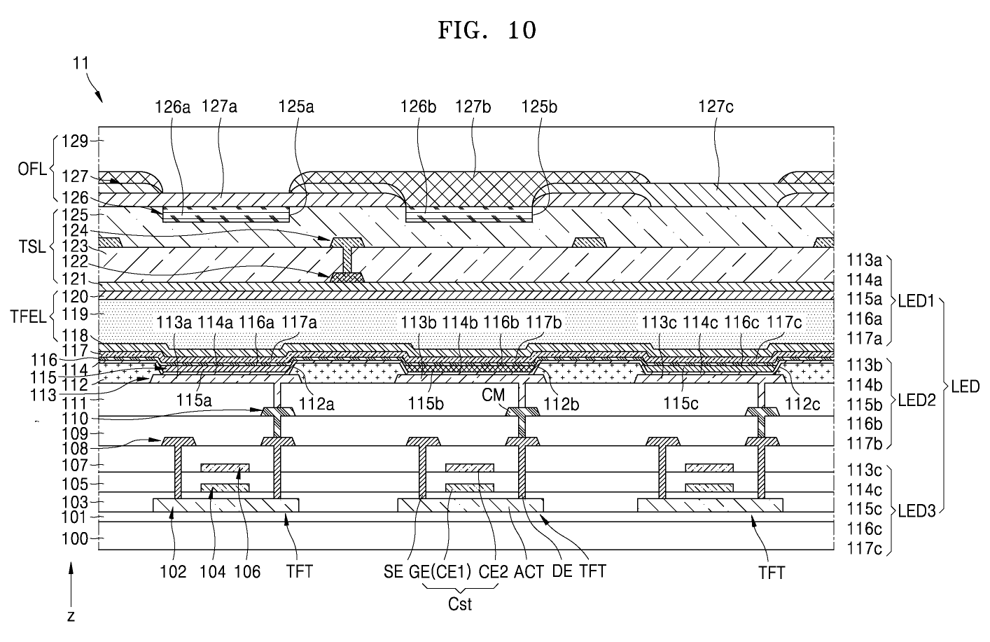

FIG. 10 is a cross-sectional view of the display panel according to an embodiment.

Referring to FIG. 10, the optical functional layer OFL might not include the first light-blocking layer 128 (see FIG. 7) or the second light-blocking layer 130 (see FIG. 9).

In an embodiment, each color filter of the color filter layer 127 may be disposed on the touch sensing layer TSL entirely, and might not be disposed on a region overlapping a light-emitting diode LED other than the corresponding light-emitting diode LED. For example, each color filter of the color filter layer 127 may include an opening overlapping a light-emitting diode LED other than the corresponding light-emitting diode LED.

In an embodiment, the first color filter 127a may overlap the first light-emitting diode LED1, the first auxiliary color filter 126a, and the pixel-defining layer 112. In an embodiment, the first color filter 127a may be open so as not to overlap the second light-emitting diode LED2 or the third light-emitting diode LED3.

In an embodiment, the second color filter 127b may overlap the second light-emitting diode LED2, the second auxiliary color filter 126b, and the pixel-defining layer 112. In an embodiment, the second color filter 127b may be open so as not to overlap the first light-emitting diode LED1 or the third light-emitting diode LED3.

In an embodiment, the third color filter 127c may overlap the third light-emitting diode LED3 and the pixel-defining layer 112. In an embodiment, the third color filter 127c may be open so as not to overlap the first light-emitting diode LED1 or the second light-emitting diode LED2.

Through the above structure, a color filter transmitting light of a corresponding color may be disposed on each light-emitting diode LED. In an embodiment, the first color filter 127a may be disposed on the first light-emitting diode LED1, the second color filter 127b may be disposed on the second light-emitting diode LED2, and the third color filter 127c may be disposed on the third light-emitting diode LED3.

In addition, respective color filters of the color filter layer 127 may overlap each other in a region between the respective light-emitting diodes LED, for example, in a region overlapping the pixel-defining layer 112. In an embodiment, the first color filter 127a, the second color filter 127b, and the third color filter 127c may overlap each other in a region overlapping the pixel-defining layer 112. In an embodiment, the third color filter 127c may be disposed on the first color filter 127a, and the second color filter 127b may be disposed on the third color filter 127c. However, the disclosure is not necessarily limited to this stacking order.

The first color filter 127a, the second color filter 127b, and the third color filter 127c may transmit light of different colors (for example, wavelength bands) from each other. Accordingly, for example, light passing through the first color filter 127a cannot pass through the second color filter 127b or the third color filter 127c. Similarly, light passing through the second color filter 127b cannot pass through the first color filter 127a or the third color filter 127c. Similarly, light passing through the third color filter 127c cannot pass through the first color filter 127a or the second color filter 127b. In an embodiment, light might not pass through an overlapping structure of the first to third color filters 127a, 127b, and 127c disposed between the respective light-emitting diodes LED. Accordingly, the overlapping structure of the first to third color filters 127a, 127b, and 127c may serve as a light-blocking layer that blocks light. For example, the first light-blocking layer 128 (see FIG. 7) and the second light-blocking layer 130 (see FIG. 9) may be replaced by the overlapping structure of the first to third color filters 127a, 127b, and 127c.

According to an embodiment, the display panel including the first and second auxiliary color filters disposed under the first and second color filters among the first to third color filters, and the electronic device including the display panel are provided. Accordingly, the quality of the display panel and/or the process (e.g., the inkjet process) of arranging the first to third color filters may be improved.

It should be understood that embodiments described herein should be considered in a descriptive sense and not necessarily for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display panel, comprising:
a substrate;
a first light-emitting diode, a second light-emitting diode, and a third light-emitting diode each disposed on the substrate and spaced apart from each other;
a touch sensing layer disposed on each of the first light-emitting diode, the second light-emitting diode, and the third light-emitting diode, the touch sensing layer having a first opening that overlaps the first light-emitting diode and a second opening that overlaps the second light-emitting diode;
a first auxiliary color filter disposed in the first opening in the touch sensing layer;
a second auxiliary color filter disposed in the second opening in the touch sensing layer;
a first color filter disposed on the touch sensing layer and overlapping the first light-emitting diode;
a second color filter disposed on the touch sensing layer and overlapping the second light-emitting diode; and
a third color filter disposed on the touch sensing layer and overlapping the third light-emitting diode,
wherein the first auxiliary color filter and the second auxiliary color filter are configured to transmit light of a same color.

2. The display panel of claim 1, wherein the first color filter is in direct contact with an upper surface of the first auxiliary color filter, and the second color filter is in direct contact with an upper surface of the second auxiliary color filter.

3. The display panel of claim 1, wherein the first auxiliary color filter and the second auxiliary color filter each include scatterers.

4. The display panel of claim 3, wherein the first auxiliary color filter has a closed loop shape overlapping an edge region of the first color filter, and the second auxiliary color filter has a closed loop shape overlapping an edge region of the second color filter.

5. The display panel of claim 1, wherein an upper surface of the first auxiliary color filter, an upper surface of the second auxiliary color filter, and an upper surface of the touch sensing layer are disposed within a same plane.

6. The display panel of claim 1, wherein the first auxiliary color filter and the second auxiliary color filter are each configured to transmit light of a color that is a combined result of first light emitted from the first light-emitting diode and second light emitted from the second light-emitting diode.

7. The display panel of claim 1, wherein the first auxiliary color filter and the second auxiliary color filter each include yellow dye.

8. The display panel of claim 1, wherein the first auxiliary color filter and the second auxiliary color filter are each configured to block light in a wavelength of 500 nm or less.

9. A display panel, comprising:
a substrate;
a first light-emitting diode disposed over the substrate and configured to emit a first light of a first color;
a second light-emitting diode disposed over the substrate and configured to emit a second light of a second color;
a third light-emitting diode disposed over the substrate and configured to emit a third light of a third color;
a first color filter overlapping the first light-emitting diode and configured to transmit light of the first color;
a second color filter overlapping the second light-emitting diode and configured to transmit light of the second color;
a third color filter overlapping the third light-emitting diode and configured to transmit light of the third color;
a first auxiliary color filter disposed between the first light-emitting diode and the first color filter; and
a second auxiliary color filter disposed between the second light-emitting diode and the second color filter,
wherein the first auxiliary color filter and the second auxiliary color filter are each configured to transmit light of a color that is a combined result of the first light and the second light.

10. The display panel of claim 9, further comprising a touch sensing layer disposed between the first to third color filters and the first to third light-emitting diodes and including a first opening that overlaps the first light-emitting diode and a second opening that overlaps the second light-emitting diode,
wherein the first auxiliary color filter is disposed in the first opening in the touch sensing layer, and
wherein the second auxiliary color filter is disposed in the second opening in the touch sensing layer.

11. The display panel of claim 10, wherein an upper surface of the first auxiliary color filter, an upper surface of the second auxiliary color filter, and an upper surface of the touch sensing layer are disposed within a same plane.

12. The display panel of claim 9, wherein the first auxiliary color filter and the second auxiliary color filter each include scatterers.

13. The display panel of claim 12, wherein the first auxiliary color filter has a closed loop shape overlapping an edge region of the first color filter, and the second auxiliary color filter has a closed loop shape overlapping an edge region of the second color filter.

14. The display panel of claim 9, wherein the first auxiliary color filter and the second auxiliary color filter each include yellow dye.

15. The display panel of claim 9, wherein the first auxiliary color filter and the second auxiliary color filter are each configured to block light in a wavelength of 500 nm or less.

16. The display panel of claim 9, wherein the first light-emitting diode, the second light-emitting diode, and the third light-emitting diode are configured to emit light of different colors from each other.

17. An electronic device, comprising:
a display panel; and
a processor configured to drive the display panel,
wherein the display panel comprises:
a substrate;
a first light-emitting diode, a second light-emitting diode, and a third light-emitting diode disposed on the substrate and spaced apart from each other;
a touch sensing layer disposed on each of the first light-emitting diode, the second light-emitting diode, and the third light-emitting diode, the touch sensing layer having a first opening that overlaps the first light-emitting diode and a second opening that overlaps the second light-emitting diode;
a first auxiliary color filter disposed in the first opening in the touch sensing layer;
a second auxiliary color filter disposed in the second opening in the touch sensing layer;
a first color filter disposed on the touch sensing layer and overlapping the first light-emitting diode;
a second color filter disposed on the touch sensing layer and overlapping the second light-emitting diode; and
a third color filter disposed on the touch sensing layer and overlapping the third light-emitting diode,
wherein the first auxiliary color filter and the second auxiliary color filter are configured to transmit light of a same color.

18. The electronic device of claim 17, wherein the first auxiliary color filter and the second auxiliary color filter each include scatterers.

19. The electronic device of claim 17, wherein the first auxiliary color filter and the second auxiliary color filter each include yellow dye.

20. The electronic device of claim 17, wherein the first auxiliary color filter and the second auxiliary color filter are each configured to block light in a wavelength of 500 nm or less.
